(19) United States
(12) Patent Application Publication
(10) Pub. No.: US 2007/0240631 A1
(43) Pub. Date: Oct. 18, 2007

(54) Epitaxial growth of compound nitride semiconductor structures

(75) Inventors: Sandeep Nijhawan, Los Altos, CA (US); David Bour, Cupertino, CA (US); Lori Washington, Union City, CA (US); Jacob Smith, Santa Clara, CA (US); Ronald Stevens, San Ramon, CA (US); David Eaglesham, Livermore, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/404,516

(22) Filed: Apr. 14, 2006

(51) Int. Cl. C30B 15/00; C30B 23/00; G06F 7/00; C30B 28/14

(52) U.S. Cl. 117/98; 117/30; 117/86; 700/220; 700/228

(57) ABSTRACT

Apparatus and methods are described for fabricating a compound nitride semiconductor structure. Group-III and nitrogen precursors are flowed into a first processing chamber to deposit a first layer over a substrate with a thermal chemical-vapor-deposition process. The substrate is transferred from the first processing chamber to a second processing chamber. Group-III and nitrogen precursors are flowed into the second processing chamber to deposit a second layer over the first layer with a thermal chemical-vapor-deposition process. The first and second group-III precursors have different group-III elements.

### BACKGROUND OF THE INVENTION

The history of light-emitting diodes (“LEDs”) is sometimes characterized as a “crawl up the spectrum.” This is because the first commercial LEDs produced light in the infrared portion of the spectrum, followed by the development of red LEDs that used GaAsP on a GaAs substrate. This was, in turn, followed by the use of GaP LEDs with improved efficiency that permitted the production of both brighter red LEDs and orange LEDs. Refinements in the use of GaP then permitted the development of green LEDs, with dual GaP chips (one in red and one in green) permitting the generation of yellow light. Further improvements in efficiency in this portion of the spectrum were later enabled through the use of GaAlAsP and InGaAlP materials.

This evolution towards the production of LEDs that provide light at progressively shorter wavelengths has generally been desirable not only for its ability to provide broad spectral coverage but because diode production of short-wavelength light may improve the information storage capacity of optical devices like CD-ROMs. The production of LEDs in the blue, violet, and ultraviolet portions of the spectrum was largely enabled by the development of nitride-based LEDs, particularly through the use of GaN. While some modestly successful efforts had previously been made in the production of blue LEDs using SiC materials, such devices suffered from poor luminescence as a consequence of the fact that their electronic structure has an indirect bandgap.

While the feasibility of using GaN to create photoluminescence in the blue region of the spectrum has been known for decades, there were numerous barriers that impeded their practical fabrication. These included the lack of a suitable substrate on which to grow the GaN structures, generally high thermal requirements for growing GaN that resulted in various thermal-convection problems, and a variety of difficulties in efficient p-doping such materials. The use of sapphire as a substrate was not completely satisfactory because it provides approximately a 15% lattice mismatch with the GaN. Progress has subsequently been made in addressing many aspects of these barriers. For example, the use of a buffer layer of AlN or GaN formed from a metalorganic vapor has been found effective in accommodating the lattice mismatch. Further refinements in the production of Ga—N-based structures has included the use of AlGaN materials to form heterojunctions with GaN and particularly the use of InGaN, which causes the creation of defects that act as quantum wells to emit light efficiently at short wavelengths. Indium-rich regions have a smaller bandgap than surrounding material, and may be distributed throughout the material to provide efficient emission centers.

While some improvements have thus been made in the manufacture of such compound nitride semiconductor devices, it is widely recognized that a number of deficiencies yet exist in current manufacturing processes. Moreover, the high utility of devices that generate light at such wavelengths has caused the production of such devices to be an area of intense interest and activity. In view of these considerations, there is a general need in the art for improved methods and systems for fabricating compound nitride semiconductor devices.

### BRIEF SUMMARY OF THE INVENTION

Embodiments of the invention provide apparatus and methods of fabricating a compound nitride semiconductor structure. A first group-III precursor and a first nitrogen precursor are flowed into a first processing chamber. The first group-III precursor comprises a first group-III element. A first layer is deposited over the substrate with a thermal chemical-vapor-deposition process within the first processing chamber using the first group-III precursor and the first nitrogen precursor so that the first layer comprises nitrogen and the first group-III element. The substrate is transferred from the first processing chamber to a second processing chamber different from the first processing chamber after depositing the first layer. A second group-III precursor and a second nitrogen precursor are flowed into the second processing chamber. The second group-III precursor comprises a second group-III element not comprised by the first group-III precursor. The second layer is deposited over the first layer with a thermal chemical-vapor-deposition process within the second processing chamber using the second group-III precursor and the second nitrogen precursor.

The transfer of the substrate from the first processing to the second processing chamber may be done under different conditions. For instance, in one embodiment, the transfer is made in an atmosphere having greater than 90% N₂; in another embodiment, it is made in an atmosphere having greater than 90% NH₃; and in still another embodiment, it is made in an atmosphere having greater than 90% H₂. The substrate may also be transferred in an atmosphere having a temperature greater than 200° C.

The precursor flows may be accompanied by carrier gas flows, examples of which include N₂ and H₂. In one embodiment, a third group-III precursor is flowed into the second processing chamber with the second group-III precursor and the second nitrogen precursor. The third group-III precursor comprises the first group-III element. Specific examples of group-III elements that may be used include the use of gallium as the first group-III element and the use of aluminum as the second group-III element, resulting in the first layer comprising a GaN layer and the second layer comprising an AlGaN layer. In another specific example, the first group-III element is gallium and the second group-III element is indium, resulting in the first layer comprising a GaN layer and the second layer comprising an InGaN layer. In still another specific example, the first group-III element is gallium and the second group-III element includes aluminum and indium, resulting in the first layer comprising a GaN layer and the second layer comprising an AlInGaN layer.

A transition layer may sometimes be deposited on the first layer in the second processing chamber before depositing the second layer. The transition layer has a chemical composition substantially the same as the first layer and a thickness less than 10,0000 Å. The first processing chamber may advantageously be adapted to provide rapid growth of material comprising nitrogen and a group-III element. The second processing chamber may advantageously be adapted to provide enhanced uniformity of deposited material comprising nitrogen and a group-III element.

Methods of the invention may be performed with a cluster tool having a first housing that defines a first processing chamber and a second housing that defines a second processing chamber. The first processing chamber includes a first substrate holder and the second processing chamber includes a second substrate holder. A robotic transfer system is adapted to transfer substrates between the first and second substrate holders in a controlled environment. A gas delivery system is configured to introduce gases into the first and second processing chambers. A pressure-control system maintains selected pressures within the first and second processing chambers, and a temperature-control system maintains selected temperatures within the first and second processing chambers. A controller controls the robotic transfer system, the gas-delivery system, the pressure-control system, and the temperature-control system. A memory is coupled to the controller and comprises a computer-readable medium having a computer-readable program. The computer-readable program includes instructions for operating the cluster tool to fabricate a compound nitride semiconductor structure.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 provides a schematic illustration of a structure of a Ga—N-based LED;

FIG. 2A is a simplified representation of an exemplary CVD apparatus that may form part of a multichamber cluster tool in embodiments of the invention;

FIG. 2B is a simplified representation of one embodiment of a user interface for the exemplary CVD apparatus of FIG. 2A;

FIG. 2C is a block diagram of one embodiment of the hierarchical control structure of the system control software for the exemplary CVD apparatus of FIG. 2A;

FIG. 3 provides a schematic illustration of a multichamber cluster tool used in embodiments of the invention;

FIG. 4 is a flow diagram summarizing methods of fabricating a compound nitride semiconductor structure using the multichamber cluster tool shown in FIG. 3; and

FIG. 5 is a flow diagram of a specific process of fabricating the LED of FIG. 1 using the multichamber cluster tool of FIG. 3.

### DETAILED DESCRIPTION OF THE INVENTION

### 1. Overview

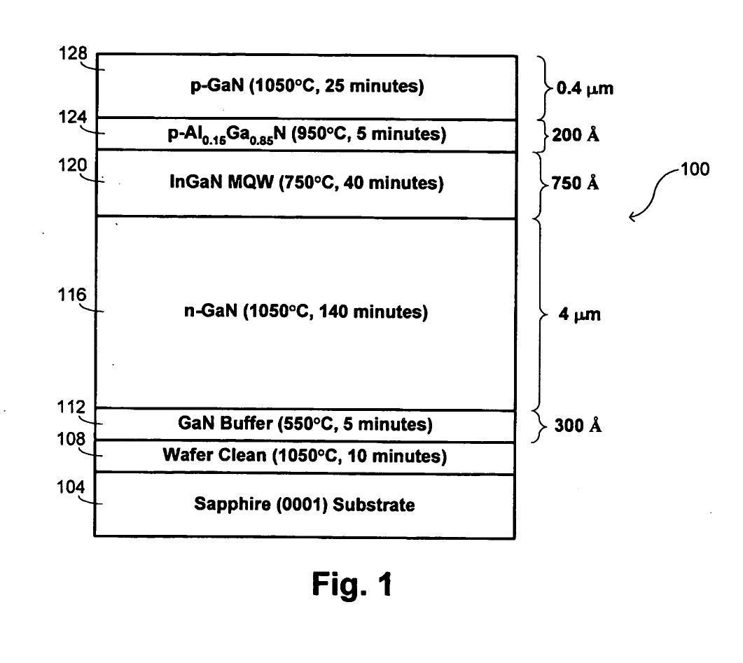

In conventional manufacturing of compound nitride semiconductor structures, multiple epitaxial deposition steps are performed in a single process reactor, with the substrate not leaving the reactor until all of the steps have been completed. The illustration in FIG. 1 shows both the types of structures that may be formed and the sequence of steps used in fabricating such a structure. In this instance, the structure is a Ga—N-based LED structure 100. It is fabricated over a sapphire (0001) substrate 104, which is subjected to a wafer cleaning procedure 108. A suitable clean time is 10 minutes at 1050° C., which may be accompanied by additional time on the order of 10 minutes for heat-up and cool-down.

A GaN buffer layer 112 is deposited over the cleaned substrate 104 using a metalorganic chemical-vapor-deposition (“MOCVD”) process. This may be accomplished by providing flows of Ga and N precursors to the reactor and using thermal processes to achieve deposition. The drawing illustrates a typical buffer layer 112 having a thickness of about 300 Å, which may be deposited at a temperature of about 550° C. for five minutes. Subsequent deposition of an n-GaN layer 116 typically occurs at a higher temperature, shown in the drawing as being performed at 1050° C. The n-GaN layer 116 is relatively thick, with deposition of a thickness on the order of 4 μm requiring about 140 minutes. This is followed by deposition of an InGaN multi-quantum-well layer 120, which may be deposited to have a thickness of about 750 Å in about 40 minutes at 750° C. A p-AlGaN layer 124 is deposited over the multi-quantum-well layer 120, with deposition of a 200-Å layer being completed in about five minutes at a temperature of 950° C. The structure may be completed with deposition of a p-GaN contact layer 128, deposited at a temperature of about 1050° C. for around 25 minutes.

Conventional fabrication with multiple epitaxial deposition steps being performed in a single reactor in a single session results in a long processing time, usually on the order of 4-6 hours. This long processing time is manifested by low reactor throughput, which is often addressed by the use of batch processing techniques. For instance, commercial reactors used in production processes may operate simultaneously on 20-50 two-inch wafers, which results in relatively poor yield.

In considering how to improve yield and throughput in techniques for fabricating compound nitride semiconductor structures, the inventors engaged in a systematic study of conventional processes to identify potential improvements. While a number of possibilities were identified, there remained certain barriers to their implementation. In many cases, this was characterized by the fact that an improvement in one portion of the process would adversely affect one or more other portions of the process. As a result of identifying the systematic nature of these types of barriers, this exercise prompted a more general recognition among the inventors that the single-reactor approach acted to prevent optimization of reactor hardware for individual steps in the process. Such limitations result in a limited process window for growth of different compound structures, as determined by such parameters as temperature, pressure, relative flow rates of precursors, and the like. Optimal deposition of GaN, for example, is not necessarily performed under the same conditions as optimal deposition of InGaN or as optimal deposition of AlGaN.

The inventors determined that the use of multiple processing chambers, as part of a multichamber cluster tool, had the potential to expand the available process window for different compound structures. This would be achieved by performing epitaxial growth of different compounds in different processing chambers having structures adapted to enhance those specific procedures. One further difficulty encountered in the actual implementation of such an approach was the further recognition that transfers among chambers within the cluster tool result in interruptions in growth sequence that may cause the occurrence of interface defect states.

The inventors developed at least two approaches to mitigating this effect. First, transfers of substrates between chambers may be performed in controlled ambient environments. For instance, in some embodiments, the controlled ambient environment has a high-purity N₂ atmosphere. As used herein, a “high-purity” X atmosphere has greater than 90% X, and may have greater than 95%, greater than 98%, or greater than 99% X in different embodiments. In other instances, the ambient environment may have a high-purity H₂ or NH₃ environment, which have the additional advantage of gettering oxygen impurities that may have formed within the structures. In still other instances, the ambient environment may have an elevated temperature at >200° C., which may also be useful for gettering or to prevent oxidation of the surface.

Second, the occurrence of interface defect states may be reduced by deposition of thin transition layers after a transfer to a new chamber. The transition layer typically has a chemical structure identical or similar to the structure of the layer deposited with the preceding chamber. Typical thicknesses of the transition layer are less than 10,000 Å, and may be less than 7500 Å, less than 5000 Å, less than 4000 Å, less than 3000 Å, less than 2500 Å, less than 2000 Å, less than 1500 Å, or less than 1000 Å in different embodiments. Specific examples of transition layers are discussed in connection with the examples provided below. A general guideline is that the transition layer preferable be sufficiently thick that any chemical contamination or structural defects be substantially removed from the active region and pn junction.

### 2. Cluster Tool

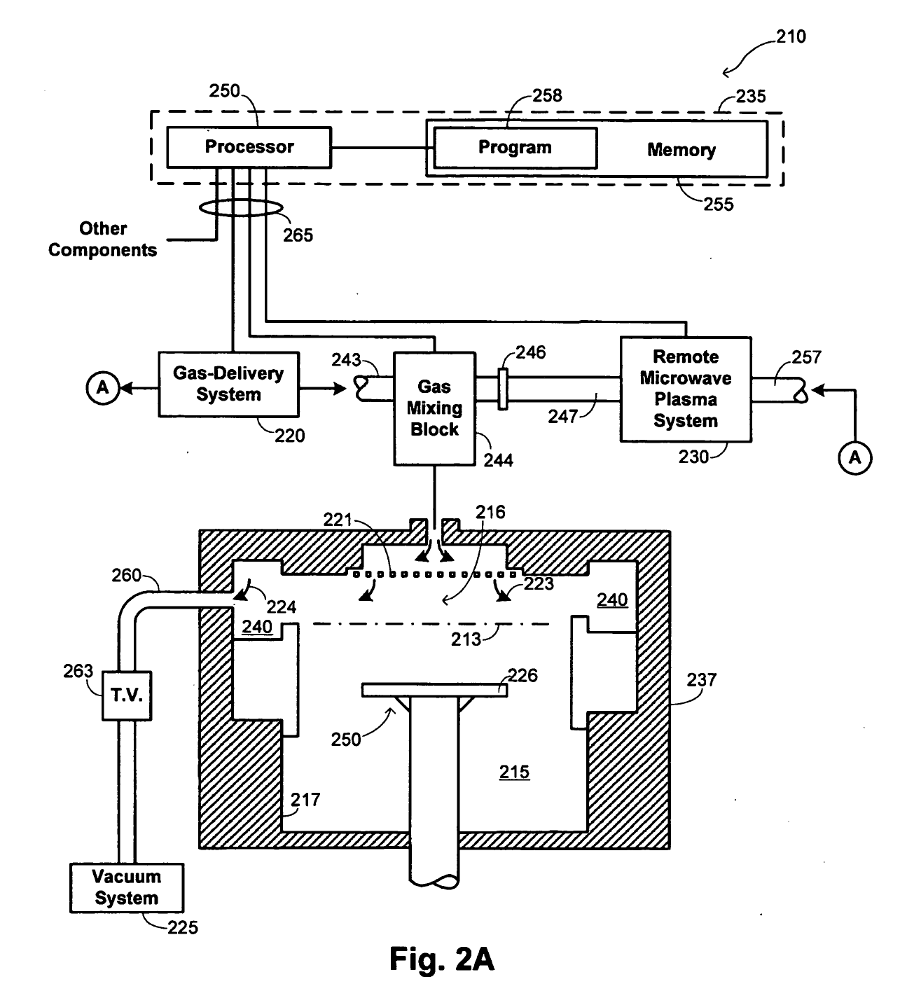

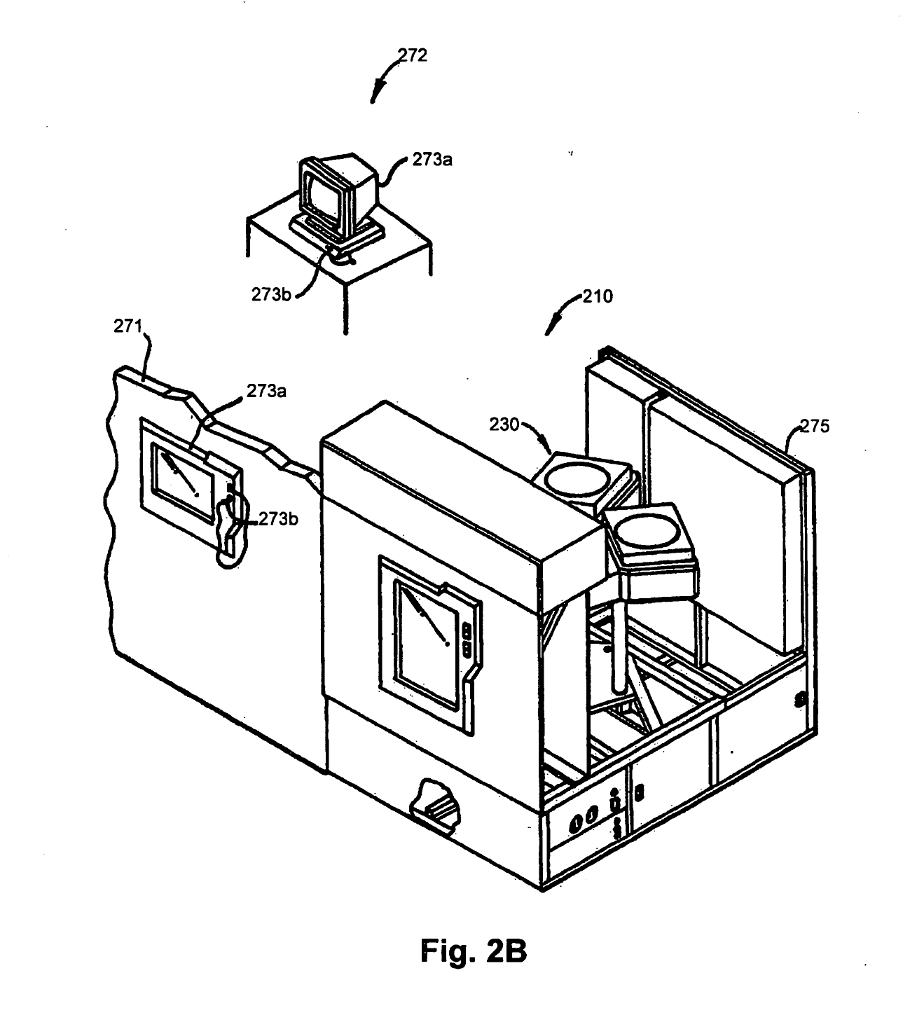

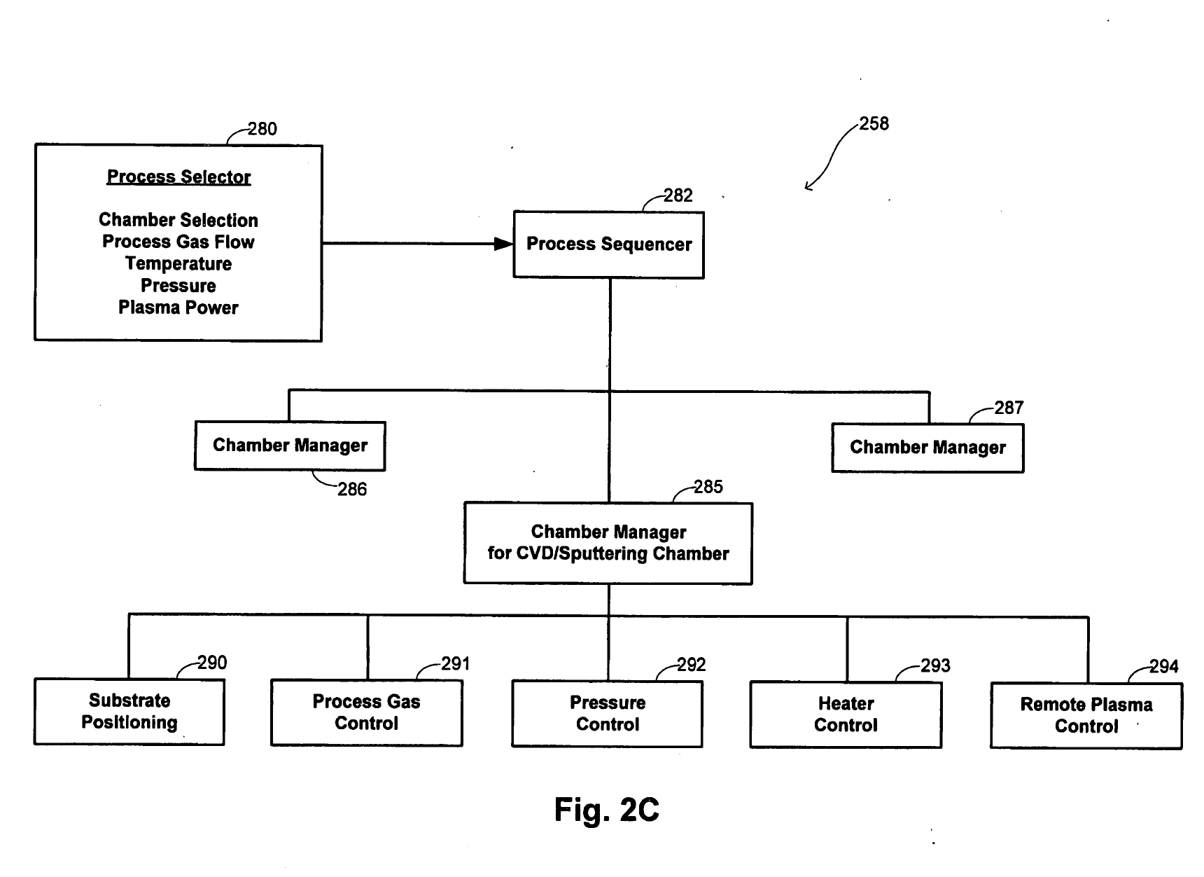

FIG. 2A is a simplified diagram of an exemplary chemical vapor deposition (“CVD”) system 210, illustrating the basic structure of individual chambers in which individual deposition steps can be performed. This system is suitable for performing thermal, sub-atmospheric CVD (“SACVD”) processes, as well as other processes, such as reflow, drive-in, cleaning, etching, deposition, and gettering processes. As will be evident from the examples described below, in some instances multiple-step processes can still be performed within an individual chamber before removal for transfer to another chamber. The major components of the system include, among others, a vacuum chamber 215 that receives process and other gases from a gas delivery system 220, a vacuum system 225, a remote plasma system 230, and a control system 235. These and other components are described in more detail below. While the drawing shows the structure of only a single chamber for purposes of illustration, it will be appreciated that multiple chambers with similar structures may be provided as part of the cluster tool, each tailored to perform different aspects of the overall fabrication process. Other components shown in the drawing for supporting the chamber processing may be shared among the multiple chambers, although in some instances individual supporting components may be provided for each chamber separately.

CVD apparatus 210 includes an enclosure assembly 237 that forms vacuum chamber 215 with a gas reaction area 216. A gas distribution plate 221 disperses reactive gases and other gases, such as purge gases, through perforated holes toward a wafer (not shown) that rests on a vertically movable heater 226 (also referred to as a wafer support pedestal). Between gas distribution plate 221 and the wafer is gas reaction area 216. Heater 226 can be controllably moved between a lower position, where a wafer can be loaded or unloaded, for example, and a processing position closely adjacent to the gas distribution plate 221, indicated by a dashed line 213, or to other positions for other purposes, such as for an etch or cleaning process. A center board (not shown) includes sensors for providing information on the position of the wafer.

Different structures may be used for heater 226 in different embodiments. For instance, in one embodiment, the heater 226 includes an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heater 226 exposed to vacuum chamber 215 are made of a ceramic material, such as aluminum oxide (Al₂O₃ or alumina) or aluminum nitride. In another embodiment, the heater 226 comprises a lamp heater. Alternatively, a bare metal filament heating element, constructed of a refractory metal such as tungsten, rhenium, iridium, thorium, or their alloys, may be used to heat the wafer. Such lamp heater arrangements are able to achieve temperatures greater than 1200° C., which may be useful for certain specific applications.

Reactive and carrier gases are supplied from gas delivery system 220 through supply lines 243 into a gas mixing box (also called a gas mixing block) 244, where they are mixed together and delivered to gas distribution plate 221. Gas delivery system 220 includes a variety of gas sources and appropriate supply lines to deliver a selected amount of each source to chamber 215 as would be understood by a person of skill in the art. Generally, supply lines for each of the gases include shut-off valves that can be used to automatically or manually shut-off the flow of the gas into its associated line, and mass flow controllers or other types of controllers that measure the flow of gas or liquid through the supply lines. Depending on the process run by system 210, some of the sources may actually be liquid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art.

Gas mixing box 244 is a dual input mixing block coupled to process gas supply lines 243 and to a cleaning/etch gas conduit 247. A valve 246 operates to admit or seal gas or plasma from gas conduit 247 to gas mixing block 244. Gas conduit 247 receives gases from an integral remote microwave plasma system 230, which has an inlet 257 for receiving input gases. During deposition processing, gas supplied to the plate 221 is vented toward the wafer surface (as indicated by arrows 223), where it may be uniformly distributed radially across the wafer surface in a laminar flow.

Purging gas may be delivered into the vacuum chamber 215 from gas distribution plate 221 and/or from inlet ports or tubes (not shown) through the bottom wall of enclosure assembly 237. Purge gas introduced from the bottom of chamber 215 flows upward from the inlet port past the heater 226 and to an annular pumping channel 240. Vacuum system 225 which includes a vacuum pump (not shown), exhausts the gas (as indicated by arrows 224) through an exhaust line 260. The rate at which exhaust gases and entrained particles are drawn from the annular pumping channel 240 through the exhaust line 260 is controlled by a throttle valve system 263.

Remote microwave plasma system 230 can produce a plasma for selected applications, such as chamber cleaning or etching residue from a process wafer. Plasma species produced in the remote plasma system 230 from precursors supplied via the input line 257 are sent via the conduit 247 for dispersion through gas distribution plate 220 to vacuum chamber 215. Remote microwave plasma system 230 is integrally located and mounted below chamber 215 with conduit 247 coming up alongside the chamber to gate valve 246 and gas mixing box 244, which is located above chamber 215. Precursor gases for a cleaning application may include fluorine, chlorine and/or other reactive elements. Remote microwave plasma system 230 may also be adapted to deposit CVD layers flowing appropriate deposition precursor gases into remote microwave plasma system 230 during a layer deposition process.

The temperature of the walls of deposition chamber 215 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during an in situ plasma process, or to limit formation of deposition products on the walls of the chamber. Gas distribution manifold 221 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

System controller 235 controls activities and operating parameters of the deposition system. System controller 235 includes a computer processor 250 and a computer-readable memory 255 coupled to processor 250. Processor 250 executes system control software, such as a computer program 258 stored in memory 270. Memory 270 is preferably a hard disk drive but may be other kinds of memory, such as read-only memory or flash memory. System controller 235 also includes a floppy disk drive, CD, or DVD drive (not shown).

Processor 250 operates according to system control software (program 258), which includes computer instructions that dictate the timing, mixture of gases, chamber pressure, chamber temperature, microwave power levels, pedestal position, and other parameters of a particular process. Control of these and other parameters is effected over control lines 265, only some of which are shown in FIG. 2A, that communicatively couple system controller 235 to the heater, throttle valve, remote plasma system and the various valves and mass flow controllers associated with gas delivery system 220.

Processor 250 has a card rack (not shown) that contains a single-board computer, analog and digital input/output boards, interface boards and stepper motor controller boards. Various parts of the CVD system 210 conform to the Versa Modular European (VME) standard which defines board, card cage, and connector dimensions and types. The VME standard also defines the bus structure having a 16-bit data bus and 24-bit address bus.

FIG. 2B is a simplified diagram of a user interface that can be used to monitor and control the operation of CVD system 210. FIG. 2B illustrates explicitly the multichamber nature of the cluster tool, with CVD system 210 being one chamber of the multichamber system. In such a multichamber system wafers may be transferred from one chamber to another via a computer-controlled robot for additional processing. In some cases the wafers are transferred under vacuum or a selected gas. The interface between a user and system controller 235 is a CRT monitor 273a and a light pen 273b. A mainframe unit 275 provides electrical, plumbing, and other support functions for the CVD apparatus 210. Exemplary multichamber system mainframe units compatible with the illustrative embodiment of the CVD apparatus are currently commercially available as the Precision 5000 and the Centura 5200™ systems from APPLIED MATERIALS, INC. of Santa Clara, Calif.

In one embodiment two monitors 273a are used, one mounted in the clean room wall 271 for the operators, and the other behind the wall 272 for the service technicians. Both monitors 273a simultaneously display the same information, but only one light pen 273b is enabled. The light pen 273b detects light emitted by the CRT display with a light sensor in the tip of the pen. To select a particular screen or function, the operator touches a designated area of the display screen and pushes the button on the pen 273b. The touched area changes its highlighted color, or a new menu or screen is displayed, confirming communication between the light pen and the display screen. As a person of ordinary skill would readily understand, other input devices, such as a keyboard, mouse, or other pointing or communication device, may be used instead of or in addition to the light pen 273b to allow the user to communicate with the processor.

FIG. 2C is a block diagram of one embodiment of the hierarchical control structure of the system control software, computer program 258, for the exemplary CVD apparatus of FIG. 2A. Processes such as those for depositing a layer, performing a dry chamber clean, or performing reflow or drive-in operations can be implemented under the control of computer program 258 that is executed by processor 250. The computer program code can be written in any conventional computer readable programming language, such as 68000 assembly language, C, C++, Pascal, Fortran, or other language. Suitable program code is entered into a single file, or multiple files, using a conventional text editor and is stored or embodied in a computer-usable medium, such as the system memory.

If the entered code text is in a high-level language, the code is compiled, and the resultant compiler code is then linked with an object code of precompiled Windows™ library routines. To execute the linked compiled object code, the system user invokes the object code, causing the computer system to load the code in memory, from which the CPU reads and executes the code to configure the apparatus to perform the tasks identified in the program.

A user enters a process set number and process chamber number into a process selector subroutine 280 by using the light pen to select a choice provided by menus or screens displayed on the CRT monitor. The process sets, which are predetermined sets of process parameters necessary to carry out specified processes, are identified by predefined set numbers. The process selector subroutine 280 identifies (i) the desired process chamber, and (ii) the desired set of process parameters needed to operate the process chamber for performing the desired process. The process parameters for performing a specific process relate to process conditions such as, for example, process gas composition and flow rates, pedestal temperature, chamber wall temperature, pressure and plasma conditions such as magnetron power levels. The process selector subroutine 280 controls what type of process (e.g. deposition, wafer cleaning, chamber cleaning, chamber gettering, reflowing) is performed at a certain time in the chamber. In some embodiments, there may be more than one process selector subroutine. The process parameters are provided to the user in the form of a recipe and may be entered utilizing the light pen/CRT monitor interface.

A process sequencer subroutine 282 has program code for accepting the identified process chamber and process parameters from the process selector subroutine 280, and for controlling the operation of the various process chambers. Multiple users can enter process set numbers and process chamber numbers, or a single user can enter multiple process set numbers and process chamber numbers, so process sequencer subroutine 282 operates to schedule the selected processes in the desired sequence. Preferably, process sequencer subroutine 282 includes program code to perform the steps of (i) monitoring the operation of the process chambers to determine if the chambers are being used, (ii) determining what processes are being carried out in the chambers being used, and (iii) executing the desired process based on availability of a process chamber and the type of process to be carried out.

Conventional methods of monitoring the process chambers, such as polling methods, can be used. When scheduling which process is to be executed, process sequencer subroutine 282 can be designed to take into consideration the present condition of the process chamber being used in comparison with the desired process conditions for a selected process, or the “age” of each particular user-entered request, or any other relevant factor a system programmer desires to include for determining scheduling priorities.

Once process sequencer subroutine 282 determines which process chamber and process set combination is going to be executed next, process sequencer subroutine 282 initiates execution of the process set by passing the particular process set parameters to a chamber manager subroutine 285 which controls multiple processing tasks in a particular process chamber according to the process set determined by process sequencer subroutine 282. For example, chamber manager subroutine 285 has program code for controlling CVD and cleaning process operations in chamber 215. Chamber manager subroutine 285 also controls execution of various chamber component subroutines which control operation of the chamber components necessary to carry out the selected process set. Examples of chamber component subroutines are substrate positioning subroutine 290, process gas control subroutine 291, pressure control subroutine 292, heater control subroutine 293 and remote plasma control subroutine 294. Depending on the specific configuration of the CVD chamber, some embodiments include all of the above subroutines, while other embodiments may include only some of the subroutines or other subroutines not described. Those having ordinary skill in the art would readily recognize that other chamber control subroutines can be included depending on what processes are to be performed in the process chamber. In multichamber systems, additional chamber manager subroutines 286, 287 control the activities of other chambers.

In operation, the chamber manager subroutine 285 selectively schedules or calls the process component subroutines in accordance with the particular process set being executed. Chamber manager subroutine 285 schedules the process component subroutines much like the process sequencer subroutine 282 schedules which process chamber and process set are to be executed next. Typically, chamber manager subroutine 285 includes steps of monitoring the various chamber components, determining which components need to be operated based on the process parameters for the process set to be executed, and initiating execution of a chamber component subroutine responsive to the monitoring and determining steps.

Operation of particular chamber component subroutines will now be described with reference to FIGS. 2A and 2C. The substrate positioning subroutine 290 comprises program code for controlling chamber components that are used to load the substrate onto the heater 226 and, optionally, to lift the substrate to a desired height in the chamber to control the spacing between the substrate and the gas distribution manifold 221. When a substrate is loaded into the process chamber 215, the heater 226 is lowered to receive the substrate and then the heater 226 is raised to the desired height. In operation, the substrate positioning subroutine 290 controls movement of the heater 226 in response to process set parameters related to the support height that are transferred from the chamber manager subroutine 285.

Process gas control subroutine 291 has program code for controlling process gas composition and flow rates. Process gas control subroutine 291 controls the state of safety shut-off valves, and also ramps the mass flow controllers up or down to obtain the desired gas flow rate. Typically, process gas control subroutine 291 operates by opening the gas supply lines and repeatedly (i) reading the necessary mass flow controllers, (ii) comparing the readings to the desired flow rates received from the chamber manager subroutine 285, and (iii) adjusting the flow rates of the gas supply lines as necessary. Furthermore, process gas control subroutine 291 includes steps for monitoring the gas flow rates for unsafe rates, and activating the safety shut-off valves when an unsafe condition is detected. Alternative embodiments could have more than one process gas control subroutine, each subroutine controlling a specific type of process or specific sets of gas lines.

In some processes, an inert gas, such as nitrogen or argon, is flowed into the chamber to stabilize the pressure in the chamber before reactive process gases are introduced. For these processes, process gas control subroutine 291 is programmed to include steps for flowing the inert gas into the chamber for an amount of time necessary to stabilize the pressure in the chamber, and then the steps described above would be carried out. Additionally, when a process gas is to be vaporized from a liquid precursor, process gas control subroutine 291 is written to include steps for bubbling a delivery gas such as helium through the liquid precursor in a bubbler assembly, or controlling a liquid injection system to spray or squirt liquid into a stream of carrier gas, such as helium. When a bubbler is used for this type of process, process gas control subroutine 291 regulates the flow of the delivery gas, the pressure in the bubbler, and the bubbler temperature in order to obtain the desired process gas flow rates. As discussed above, the desired process gas flow rates are transferred to process gas control subroutine 291 as process parameters.

Furthermore, process gas control subroutine 291 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The pressure control subroutine 292 includes program code for controlling the pressure in the chamber by regulating the aperture size of the throttle valve in the exhaust system of the chamber. The aperture size of the throttle valve is set to control the chamber pressure at a desired level in relation to the total process gas flow, the size of the process chamber, and the pumping set-point pressure for the exhaust system. When the pressure control subroutine 292 is invoked, the desired or target pressure level is received as a parameter from the chamber manager subroutine 285. Pressure control subroutine 292 measures the pressure in the chamber by reading one or more conventional pressure manometers connected to the chamber, compares the measure value(s) to the target pressure, obtains proportional, integral, and differential (“PID”) values corresponding to the target pressure from a stored pressure table, and adjusts the throttle valve according to the PID values. Alternatively, the pressure control subroutine 292 can be written to open or close the throttle valve to a particular aperture size, i.e. a fixed position, to regulate the pressure in the chamber. Controlling the exhaust capacity in this way does not invoke the feedback control feature of the pressure control subroutine 292.

Heater control subroutine 293 includes program code for controlling the current to a heating unit that is used to heat the substrate. Heater control subroutine 293 is also invoked by the chamber manager subroutine 285 and receives a target, or set-point, temperature parameter. Heater control subroutine 293 measures the temperature, which may be performed in different ways in different embodiments. For instance, a calibrated temperature may be determined by measuring voltage output of a thermocouple located in the heater, comparing the measured temperature to the set-point temperature, and increasing or decreasing current applied to the heating unit to obtain the set-point temperature. The temperature is obtained from the measured voltage by looking up the corresponding temperature in a stored conversion table, or by calculating the temperature using a fourth-order polynomial. In another embodiment, a similar process may be performed with a pyrometer instead of a thermocouple to determine a calibrated temperature. Heater control subroutine 293 includes the ability to gradually control a ramp up or down of the heater temperature. In embodiments where the heater comprises a resistive heating element enclosed in ceramic, this feature helps to reduce thermal cracking in the ceramic, although this is not a concern in those embodiments that use a lamp heater Additionally, a built-in fail-safe mode can be included to detect process safety compliance, and can shut down operation of the heating unit if the process chamber is not properly set up.

Remote plasma control subroutine 294 includes program code to control the operation of remote plasma system 230. Plasma control subroutine 294 is invoked by chamber manager 285 in a manner similar to the other subroutines just described.

Although the invention is described herein as being implemented in software and executed upon a general purpose computer, those of skill in the art will realize that the invention could be implemented using hardware such as an application specific integrated circuit (ASIC) or other hardware circuitry. As such, it should be understood that the invention can be implemented, in whole or in part, is software, hardware or both. Those skilled in the art will also realize that it would be a matter of routine skill to select an appropriate computer system to control CVD system 210.

### 3. Multichamber Processing

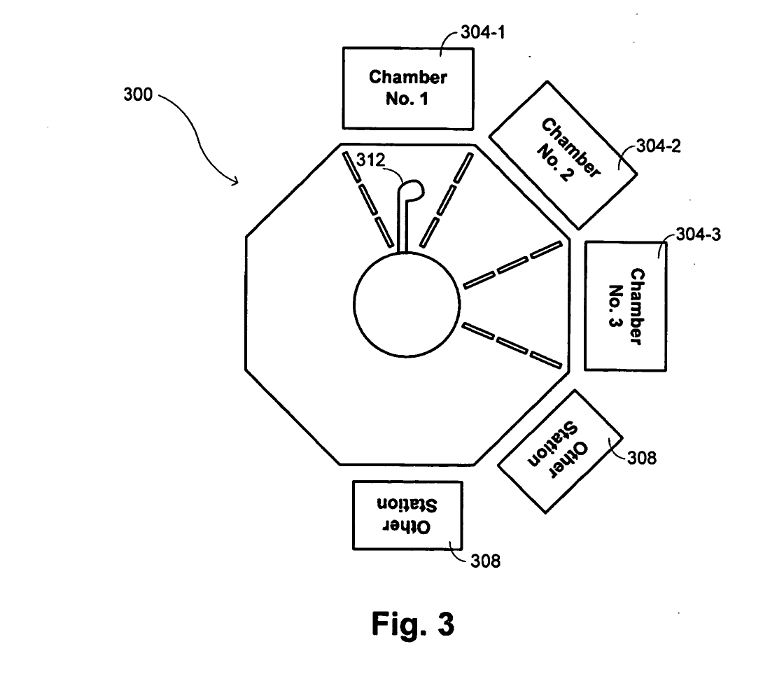

The physical structure of the cluster tool is illustrated schematically in FIG. 3. In this illustration, the cluster tool 300 includes three processing chambers 304 and two additional stations 308, with robotics 312 adapted to effect transfers of substrates between the chambers 304 and stations 308. The structure permits the transfers to be effected in a defined ambient environment, including under vacuum, in the presence of a selected gas, under defined temperature conditions, and the like.

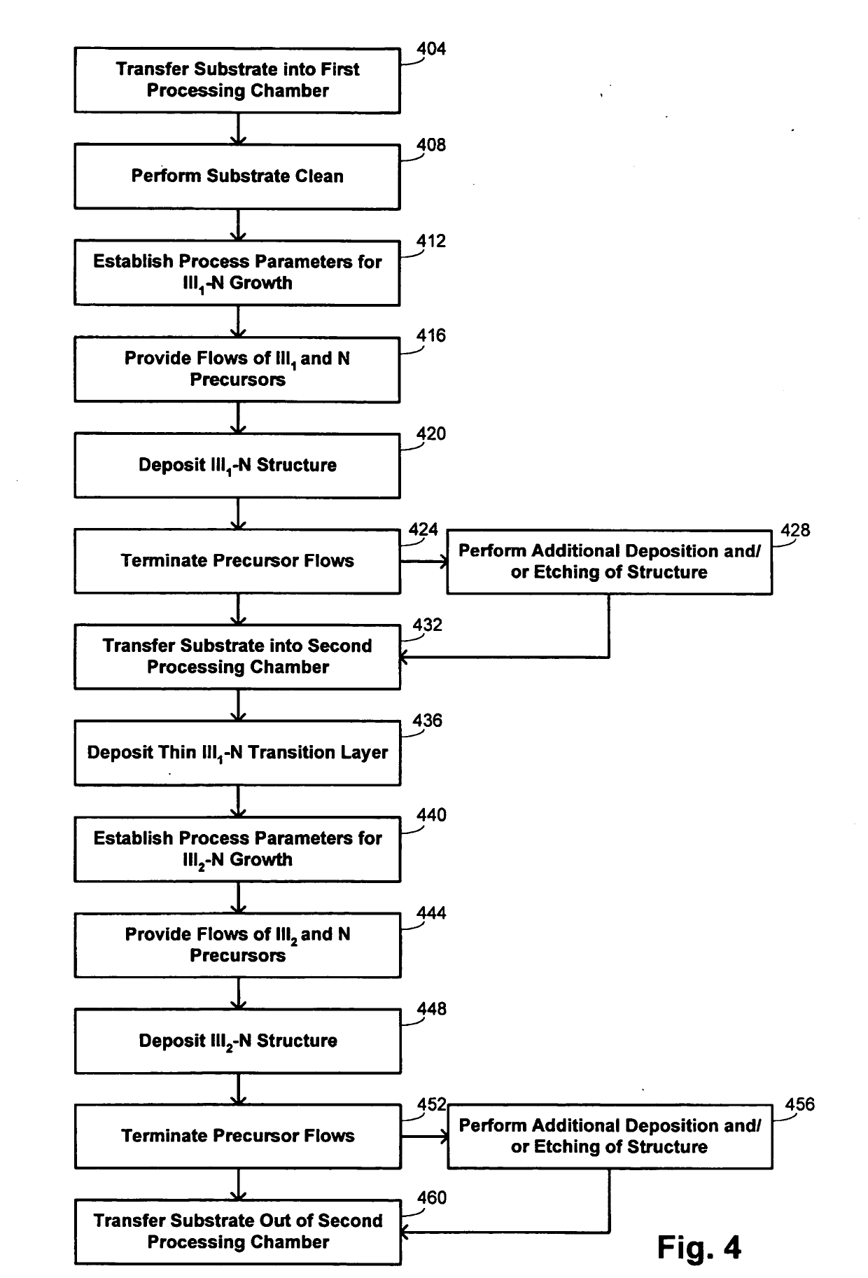

An overview of processing methods for fabricating a compound nitride semiconductor structure with the cluster tool is provided with the flow diagram of FIG. 4. The process begins at block 404 by using the robotics 312 to transfer a substrate into a first of the processing chambers 304-1. The substrate is cleaned in the first processing chamber at block 408. Deposition of an initial epitaxial layer is initiated at block 412 by establishing desired processing parameters within the first processing chamber, such as temperature, pressure, and the like. Flows of precursors are provided at block 416 to deposit a III₁-N structure at block 420. The precursors include a nitrogen source and a source for a first group-III element such as Ga. For instance, suitable nitrogen precursors include NH₃ and suitable Ga precursors include trimethyl gallium (“TMG”). The first group-III element may sometimes comprise a plurality of distinct group-III elements such as Al and Ga, in which case a suitable Al precursor may be trimethyl aluminum (“TMA”); in another example, the plurality of distinct group-III elements includes In and Ga, in which case a suitable In precursor may be trimethyl indium (“TMI”). A flow of a carrier gas such as N₂ and/or H₂ may also be included.

After deposition of the III₁-N structure at block 420, the precursor flows are terminated at block 424. In some instances, additional processing may be performed on the structure at block 428 by performing further deposition or etching steps, or a combination of deposition and etching steps.

Irrespective of whether additional steps are performed on the III₁-N structure, the substrate is transferred from the first processing chamber to a second processing chamber at block 432. Such a transfer may take place in a high-purity N₂ environment, in a high-purity H₂ environment, or in a high-purity NH₃ environment in different embodiments; in some instances, the transfer environment may be at elevated temperature as described above. A thin III₁-N transition layer is deposited over the III₁-N structure as indicated at block 436. Deposition of the transition layer may be performed in a manner similar to the deposition of the III₁-N structure, generally using the same precursors as were used in the first chamber, although in some cases different precursors may be used.

Deposition of the III₂-N layer is performed by establishing suitable processing parameters such as temperature, pressure, and the like for such deposition at block 440. Flows of precursor gases are provided at block 444 to enable the III₂-N structure to be deposited at block 448. This structure includes a group-III element that is not comprised by the III₁-N layer, although the III₁-N and III₂-N layers may additionally comprise a common group-III element. For instance, in the case where the III₁-N layer is GaN, the III₂-N layer may be an AlGaN layer or an InGaN layer. While these are examples in which the III₂-N layer has a ternary composition, this is not required by the invention and the III₂ layer may more generally include such other compositions as quaternary AlInGaN layers. Similarly, in the case where the III₁-N layer is AlGaN, the III₂-N layer may be an InGaN layer on an AlInGaN layer. Suitable precursors for deposition of the III₂-N layer may be similar to the precursors used for the III₁ layer, i.e. NH₃ is a suitable nitrogen precursor, TMG is a suitable gallium precursor, TMA is a suitable aluminum precursor, and TMI is a suitable indium precursor. A carrier case such a N₂ and/or H₂ may also be included. After deposition of the III₂-N structure, the precursor flows are terminated at block 452.

Similar to the deposition of the III₁-N structure, some additional processing may be performed on the deposited III₂-N structure with deposition and/or etching, as indicated at block 456. When the processing in the second chamber is completed, the substrate is transferred out of the chamber at block 460. In some instances, processing may be completed in the two chambers so that the structure is complete at block 460. In other instances, the transfer out of the second chamber at block 460 may instead be followed by a transfer into another chamber, either into the first chamber for further III₁-N processing or into yet a third chamber for III₃-N processing. A sequence of transfers among the different chambers may be performed as appropriate for fabrication of the specific device, thereby exploiting the particular process windows enabled by the different chambers. The invention is not limited by any particular number of processing chambers that may be used in a particular fabrication process nor by any particular number of times processes are performed in any the individual chambers of the cluster tool.

Merely by way of example, one of the processing chambers may be configured to enhance the deposition rate of GaN deposition and a second of the processing chambers may be configured to enhance the uniformity of deposition. In many structures, the total processing time may be highly dependent on the deposition rate of GaN because it provides the thickest layer in the completed structure. Having a first chamber optimized to increase GaN growth thus significantly improves overall tool productivity. At the same time, the hardware characteristics that permit fast growth of GaN may be relatively poorly suited for growth of InGaN quantum wells, which often provide the active emission centers. Growth of such structures generally requires greater uniformity characteristics, which are manifested by improved wavelength uniformity in the luminescent structures that are produced. Optimization of precursor distribution to improve wafer uniformity may be at the expense of growth rate. Having a second processing chamber optimized to provide highly uniform deposition for InGaN multi-quantum-well structures thus permits the uniformity objectives to be achieved without greatly compromising the overall processing time for the entire structure.

The processing conditions established at blocks 412 and 440 and the precursor flows provided at blocks 416 and 444 may vary depending on specific applications. The following table provides exemplary processing conditions and precursor flow rates that are generally suitable in the growth of nitride semiconductor structures using the devices described above:

| Parameter | Value |
|---|---|
| Temperature (° C.) | 500 - 1500 |
| Pressure (torr) | 50 - 1000 |
| TMG flow (sccm) | 0 - 50 |
| TMA flow (sccm) | 0 - 50 |
| TMI flow (sccm) | 0 - 50 |
| PH₃ flow (sccm) | 0 - 1000 |
| AsH₃ flow (sccm) | 0 - 1000 |
| NH₃ flow (sccm) | 100 - 100,000 |
| N₂ flow (sccm) | 0 - 100,000 |
| H₂ flow (sccm) | 0 - 100,000 |

As will be evident from the preceding description, a process might not use flows of all the precursors in any given process. For example, growth of GaN might use flows of TMG, NH₃, and N₂ in one embodiment; growth of AlGaN might use flows of TMG, TMA, NH₃, and H₂ in another embodiment, with the relative flow rates of TMA and TMG selected to provide a desired relative Al:Ga stoichiometry of the deposited layer; and growth of InGaN might use flows of TMG, TMI, NH₃, N₂, and H₂ in still another embodiment, with relative flow rates of TMI and TMG selected to provide a desired relative In:Ga stoichiometry of the deposited layer.

The table also notes that group-V precursors different from nitrogen may also sometimes be included. For example, a III-N—P structure may be fabricated by including a flow of phosphine PH₃ or a III-N—As structure may be fabricated by including a flow of arsine AsH₃. The relative stoichiometry of the nitrogen to the other group-V element in the structure may be determined by suitable choices of relative flow rates of the respective precursors. In still other instances, doped compound nitride structures may be formed by including dopant precursors, particular examples of which include the use of rare-earth dopants.

Use of a plurality of processing chambers as part of the cluster tool for the fabrication of nitride structures additionally permits improvements in chamber cleaning operations. It is generally desirable that each nitride-structure growth run start from a clean susceptor to provide as good a nucleation layer as possible. By using a plurality of processing chambers, it is possible to clean the first processing chamber prior to each growth run, but to clean the second processing chamber less frequently without adversely affecting the quality of the fabricated structures. This is because each structure provided to the second processing chamber already has a nitride layer. This in turn improves productivity and extends the hardware lifetime of at least the second processing chamber.

Other efficiencies ensue from the use of multiple processing chambers. For example, it was previously noted that for the structure shown in FIG. 1, deposition of the n-GaN layer 116 is most time consuming because it is the thickest. An arrangement may be used in which multiple processing chambers are used simultaneously to deposit the n-GaN layers, but with staggered start times. A single additional processing chamber is used for deposition of the remaining structures, which are received in an interleaved fashion from the processing chambers adapted for rapid GaN deposition. This avoids having the additional processing chamber sit idle while deposition of an n-GaN layer takes place, thereby improving overall throughput, particularly when coupled with the ability to reduce the cleaning cycle of the additional processing chamber. In some instances, this capability provides economic feasibility for the fabrication of certain nitride structures that are not economical with other processing techniques; this is the case, for instance, with devices that include GaN layers approaching thicknesses of 10 μm.

### 4. Example

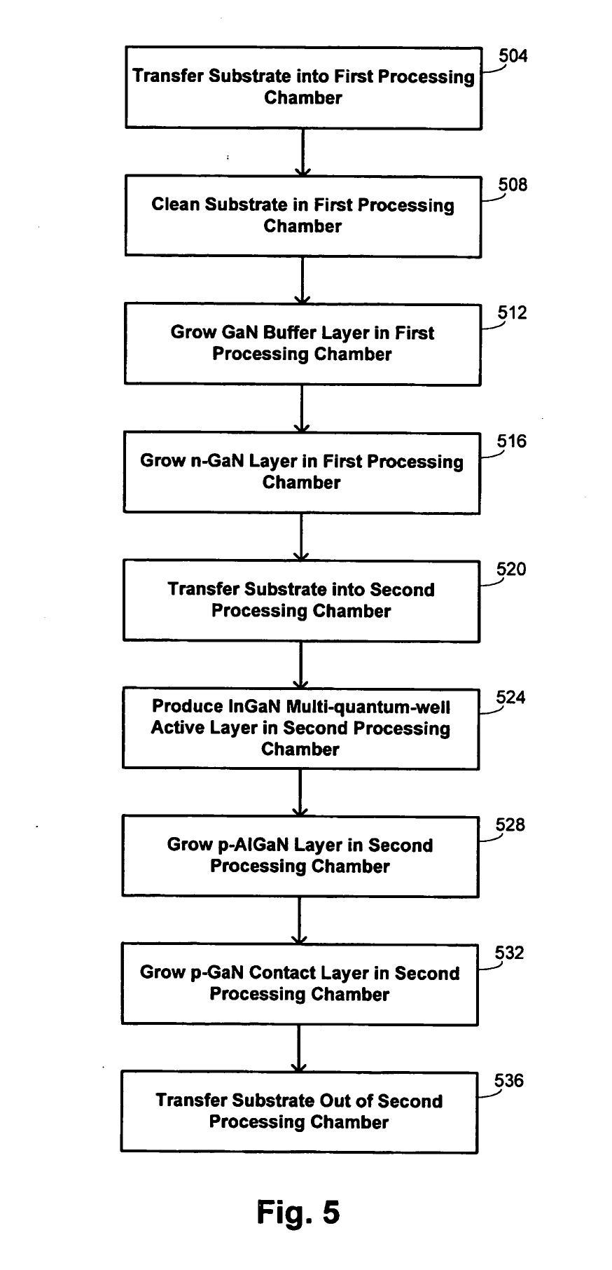

The following example is provided to illustrate how the general process described in connection with FIG. 4 may be used for the fabrication of specific structures. The example refers again to the LED structure illustrated in FIG. 1, with its fabrication being performed using a cluster tool having at least two processing chambers. An overview of the process is provided with the flow diagram of FIG. 5. Briefly, the cleaning and deposition of the initial GaN layers is performed in a first processing chamber, with growth of the remaining InGaN, AlGaN, and GaN contact layers being performed in a second processing chamber.

The process begins at block 504 of FIG. 5 with the sapphire substrate being transferred into the first processing chamber. The first processing chamber is configured to provide rapid deposition of GaN, perhaps at the expense of less uniformity in deposition. The first processing chamber will usually have been cleaned prior to such transfer and the substrate is cleaned within the chamber at block 508. The GaN buffer layer 112 is grown over the substrate in the first processing chamber at block 512 using flows of TMG, NH₃, and N₂ at a temperature of 550° C. and a pressure of 150 torr in this example. This is followed at block 516 by growth of the n-GaN layer 116, which in this example is performed using flows of TMG, NH₃, and N₂ at a temperature of 1100° C. and a pressure of 150 torr.

After deposition of the n-GaN layer, the substrate is transferred out of the first processing chamber and into the second processing chamber, with the transfer taking place in a high-purity N₂ atmosphere. The second processing chamber is adapted to provide highly uniform deposition, perhaps at the expense of overall deposition rate. In the second processing chamber, the InGaN multi-quantum-well active layer is grown at block 524 after deposition of a transition GaN layer at block 520. In this example, the InGaN layer is grown with TMG, TMI, and NH₃ precursors provided in a H₂ carrier-gas flow at a temperature of 800° C. and a pressure of 200 torr. This is followed by deposition of the p-AlGaN layer at block 528 using TMG, TMA, and NH₃ precursors provided in a H₂ carrier-gas flow at a temperature of 1000° C. and a pressure of 200 torr. Deposition of the p-GaN contact layer at block 532 is performed using flows of TMG, NH₃, and N₂ at temperature of 1000° C. and a pressure of 200 torr.

The completed structure is then transferred out of the second processing chamber at block 536 so that the second processing chamber is ready to receive an additional partially processed substrate from the first processing chamber or from a different third processing chamber.

Having fully described several embodiments of the present invention, many other equivalent or alternative methods of producing the cladding layers of the present invention will be apparent to those of skill in the art. These alternatives and equivalents are intended to be included within the scope of the invention, as defined by the following claims.

What is claimed is:

1. A method of fabricating a compound nitride semiconductor structure, the method comprising:
flowing a first group-III precursor and a first nitrogen precursor into a first processing chamber, the first group-III precursor comprising a first group-III element;
depositing a first layer over the substrate with a thermal chemical-vapor-deposition process within the first processing chamber using the first group-III precursor and the first nitrogen precursor, the first layer comprising nitrogen and the first group-III element;
transferring the substrate from the first processing chamber to a second processing chamber different from the first processing chamber after depositing the first layer;
flowing a second group-III precursor and a second nitrogen precursor into the second processing chamber, the second group-III precursor comprising a second group-III element not comprised by the first group-III precursor; and
depositing a second layer over the first layer with a thermal chemical-vapor-deposition process within the second processing chamber using the second group-III precursor and the second nitrogen precursor.

2. The method recited in claim 1 wherein transferring the substrate from the first processing chamber to the second processing chamber comprises transferring the substrate in an atmosphere having greater than 90% N₂.

3. The method recited in claim 1 wherein transferring the substrate from the first processing chamber to the second processing chamber comprises transferring the substrate in an atmosphere having greater than 90% NH₃.

4. The method recited in claim 1 wherein transferring the substrate from the first processing chamber to the second processing chamber comprises transferring the substrate in an atmosphere having greater than 90% H₂.

5. The method recited in claim 1 wherein transferring the substrate from the first processing chamber to the second processing chamber comprises transferring the substrate in an atmosphere having a temperature greater than 200° C.

6. The method recited in claim 1 further comprising flowing a first carrier gas with the first group-III precursor and the first nitrogen precursor, wherein the first carrier gas is selected from the group consisting of N₂ and H₂.

7. The method recited in claim 6 further comprising flowing a second carrier gas with the second group-III precursor and the second nitrogen precursor, wherein the second carrier gas is selected from the group consisting of N₂ and H₂.

8. The method recited in claim 1 further comprising flowing a third group-III precursor into the second processing chamber with the second group-III precursor and the second nitrogen precursor, wherein the third group-III precursor comprises the first group-III element.

9. The method recited in claim 8 wherein:
the first group-III element is gallium;
the second group-III element is aluminum;
the first layer comprises a GaN layer; and
the second layer comprises an AlGaN layer.

10. The method recited in claim 8 wherein:
the first group-III element is gallium;
the second group-III element is indium;
the first layer comprises a GaN layer; and
the second layer comprises an InGaN layer.

11. The method recited in claim 8 wherein:
the first group-III element is gallium;
the second group-III element includes aluminum and indium;
the first layer comprises a GaN layer; and
the second layer comprises an AlInGaN layer.

12. The method recited in claim 1 wherein the first group-III precursor comprises a gallium precursor and the first layer comprises a GaN layer.

13. The method recited in claim 1 further comprising depositing a transition layer on the first layer in the second processing chamber before depositing the second layer, the transition layer having a chemical composition substantially the same as the first layer and having a thickness less than 10,000 Å.

14. The method recited in claim 1 wherein the first processing chamber is adapted to provide rapid growth of material comprising nitrogen and a group-III element.

15. The method recited in claim 1 wherein the second processing chamber is adapted to provide enhanced uniformity of deposited material comprising nitrogen and a group-III element.

16. The method recited in claim 1 further comprising:
flowing a third group-III precursor and a third nitrogen precursor into a third processing chamber different from the first and second processing chambers, the third group-III precursor comprising a third group-III element;
depositing a third layer over a second substrate with a thermal chemical-vapor-deposition process within the third processing chamber using the third group-III precursor and the third nitrogen precursor, the third layer comprising nitrogen and the third group-III element;
transferring the substrate out of the second processing chamber; and
transferring the second substrate from the third processing chamber into the second processing chamber after transferring the substrate out of the second processing chamber to deposit a fourth layer over the third layer within the second processing chamber.

17. The method recited in claim 16 wherein the second processing chamber is not cleaned between transferring the substrate out of the second processing chamber and transferring the second substrate into the second processing chamber.

18. A method of fabricating a compound nitride semiconductor structure, the method comprising:
flowing a first gallium-containing precursor, a first nitrogen-containing precursor, and a first carrier gas into a first processing chamber, the first processing chamber being adapted to provide rapid growth of GaN;
depositing a GaN layer over the substrate with a thermal chemical-vapor-deposition process within the first processing chamber using the first gallium-containing precursor and the first nitrogen-containing precursor;
transferring the substrate from the first processing chamber to a second processing chamber in a high-purity atmosphere, the second processing chamber being adapted to provide enhanced uniformity of deposited material;
depositing a Ga transition layer having a thickness less than 10,000 Å on the GaN layer in the second processing chamber;
flowing a second gallium-containing precursor, a group-III precursor, a second nitrogen-containing precursor, and a second carrier gas into the second processing chamber, the group-III precursor comprising a group-III element different from gallium; and
depositing an group-III-Ga—N layer over the GaN transition layer with a thermal chemical-vapor-deposition process within the second processing chamber using the second gallium-containing precursor, the group-III precursor, and the second nitrogen-containing precursor.

19. The method recited in claim 18 wherein the group-III precursor is an aluminum-containing precursor and the group-III-Ga—N layer is an AlGaN layer.

20. The method recited in claim 18 wherein the group-III precursor is an indium-containing precursor and the group-III-Ga—N layer is an InGaN layer.

21. The method recited in claim 18 wherein the group-III precursor includes an aluminum-containing precursor and an indium-containing precursor and the group-III-Ga—N layer is an AlInGaN layer.

22. A cluster tool comprising:
a first housing defining a first processing chamber that includes a first substrate holder;
a second housing defining a second processing chamber that includes a second substrate holder, the second processing chamber being different from the first processing chamber;
a robotic transfer system adapted to transfer substrates between the first and second substrate holders in a controlled environment;
a gas-delivery system configured to introduce gases into the first and second processing chambers;
a pressure-control system for maintaining selected pressures within the first and second processing chambers;
a temperature-control system for maintaining selected temperatures within the first and second processing chambers;
a controller for controlling the robotic transfer system the gas-delivery system, the pressure-control system, and the temperature-control system; and
a memory coupled to the controller, the memory comprising a computer-readable medium having a computer-readable program embodied therein for directing operation of the cluster tool, the computer-readable program including:
instructions to control the gas-delivery system to flow a first group-III precursor, a first nitrogen precursor, and a first carrier gas into the first processing chamber, the first group-III precursor comprising a first group-III element;
instructions to control the pressure-control system and the temperature-control system to deposit a first layer over the substrate with a thermal chemical-vapor-deposition process within the first processing chamber, the first layer comprising nitrogen and the first group-III element;
instructions to control the robotic transfer system to transfer the substrate from the first processing chamber to the second processing chamber after depositing the first layer;
instructions to control the gas-delivery system to flow a second group-III precursor, a second nitrogen precursor, and a second carrier gas into the second processing chamber, the second group-III precursor comprising a second group-III element not comprised by the first group-III precursor; and
instructions to control the pressure-control system and the temperature-control system to deposit a second layer over the first layer with a thermal chemical-vapor-deposition process within the second processing chamber.

23. The cluster tool recited in claim 22 wherein the substrate is transferred from the first processing chamber to the second processing chamber in an atmosphere having greater than 90% N₂, greater than 90% NH₃, or greater than 90% H₂.

24. The cluster tool recited in claim 22 wherein the substrate is transferred from the first processing chamber to the second processing chamber in an atmosphere having a temperature greater than 200° C.

25. The cluster tool recited in claim 22 wherein the computer-readable program further includes instructions to control the gas-delivery system to flow a third group-III precursor into the second processing chamber with the second group-III precursor and the second nitrogen precursor, wherein the third group-III precursor comprises the first group-III element.

26. The cluster tool recited in claim 22 wherein:
the first group-III element is gallium;
the second group-III element is aluminum;
the first layer comprises a GaN layer; and
the second layer comprises an AlGaN layer.

27. The cluster tool recited in claim 22 wherein:
the first group-III element is gallium;
the second group-III element is indium;
the first layer comprises a GaN layer; and
the second layer comprises an InGaN layer.

28. The cluster tool recited in claim 22 wherein:
the first group-III element is gallium;
the second group-III element includes aluminum and indium;
the first layer comprises a GaN layer; and
the second layer comprises an AlInGaN layer.

29. The cluster tool recited in claim 22 wherein the computer-readable program further includes instructions to control the gas-delivery system, pressure-control system, and temperature-control system to deposit a transition layer on the first layer in the second processing chamber before depositing the second layer, the transition layer having a chemical composition substantially the same as the first layer.

30. The cluster tool recited in claim 22 wherein the first processing chamber is adapted to provide rapid growth of material comprising nitrogen and a group-III element.

31. The cluster tool recited in claim 22 wherein the second processing chamber is adapted to provide enhanced uniformity of deposited material comprising nitrogen and a group-III element.
